(19) United States
(12) Patent Application Publication
(10) Pub. No.: US 2007/0215988 A1
(43) Pub. Date: Sep. 20, 2007

(54) Semiconductor Device Including a Plurality of Semiconductor Chips Packaged in a Common Housing

(75) Inventor: Peter Poechmueller, XiAn (CN)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munchen (DE)

(21) Appl. No.: 11/685,821

(22) Filed: Mar. 14, 2007

(30) Foreign Application Priority Data
Mar. 15, 2006 (DE) 10 2006 011 967.3

(51) Int. Cl. H01L 29/40

(52) U.S. Cl. 257/664

(57) ABSTRACT

A semiconductor device includes a plurality of semiconductor chips packaged in a common housing. The semiconductor chips include signal pads to pass critical signals to respective chips and are terminated by a terminating resistance. At least one set of signal pads, arranged on different chips and in close proximity to one another, are connected and pass the same signal. The signal pads are terminated by the terminating resistance.

### CROSS REFERENCE TO RELATED APPLICATIONS

This application claims priority under 35 U.S.C. §119 to Application No. DE 10 2006 011 967.3 filed on Mar. 15, 2006, entitled “Semiconductor device having a plurality of semiconductor chips which are packaged in a common housing, and semiconductor chips which are set up for this purpose,” the entire contents of which are hereby incorporated by reference.

### BACKGROUND

Semiconductor devices having a plurality of chips which are packaged in a housing are taking up an increasingly large part of the semiconductor market. The same applies to semiconductor chips which are produced for such purposes. Terminating resistances or impedances are being provided more and more frequently on the chip under such semiconductor chips. This applies, in particular, to semiconductor chips which receive signals at a very high signal transmission frequency, as is the case with DDR-2 DRAM semiconductor memory chips, for example.

Types of impedance matching which are conventional and typical in the prior art are explained with reference to the accompanying FIGS. 5A, 5B and 5C. According to FIG. 5A, a terminating resistance RT is connected to a pad P on the semiconductor chip, to be precise in order to terminate a signal, for example an address signal, which is received by a receiver RX in this case. Although not described here, the same concept applies to pads which pass output signals from the chip. The terminating resistance RT effects impedance matching or noise matching. In a 50 Ω signal transmission system, a value of 50 Ω would be selected for the terminating resistance RT. Terminating resistances on output lines are usually inactive as long as the signal driver is activated and are only activated when the signal driver is inactive.

FIG. 5B shows one possible way of realizing a 50 Ω terminating resistance. In this case, the terminating resistance RT is realized using two MOS transistors each having an impedance of 100 Ω. This is referred to as symmetrical termination and a dedicated supply voltage which is generally symmetrical to the average signal potential is respectively applied to the two MOS transistors in this case. The two 100 Ω impedances shown in FIG. 5B produce a 50 Ω terminating resistance when taken together.

FIG. 5C shows an asymmetrical terminating resistance which has been realized using a single MOS transistor with an impedance of 50 Ω.

Instead of using MOS transistors as in FIGS. 5A to 5C, such terminating resistances can also be realized using other techniques, for example with the aid of polysilicon line sections, metal line sections and diffused line sections, which can also be used to realize a permanent resistance.

For the situation in which an individual signal line conducts a signal to signal pads on a plurality of chips which are packaged in a common housing, terminating resistances should be provided such that inactive pads do not interfere with signal propagation as a result of reflection.

### SUMMARY

A semiconductor device including a plurality of semiconductor chips packaged in a common housing is described herein. The semiconductor chips include signal pads for passing critical signals to the respective chip and are terminated by a terminating resistance. At least two signal pads, arranged on different chips and in close proximity to one another, are connected and pass the same signal. The signal pads are terminated by the terminating resistance.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The semiconductor device and semiconductor chip are explained in more detail below with reference to exemplary embodiments, where:

FIG. 1A schematically shows a flip-chip arrangement of two chips which are packaged in a common housing (not shown);

FIG. 1B schematically shows the arrangement of a terminating resistance in only one of the two chips shown in FIG. 1A;

FIG. 2A schematically shows the arrangement of two chips which are stacked on top of one another and have bonding wires which are routed to their top side;

FIG. 2B schematically shows the arrangement of a terminating resistance on a pad of a chip whose connecting line or bonding wire is longer than the connecting line or bonding wire to the other chip;

FIG. 3 schematically shows the arrangement of two pads, which each pass the same signal, and a selection circuit for selecting two different terminating resistances of a chip;

FIG. 4 shows an embodiment of the semiconductor chip including a selection circuit for selecting terminating resistances of different impedance in the semiconductor chip; and

FIGS. 5A-5C show different types of termination on a signal line of a semiconductor chip.

### DETAILED DESCRIPTION

Described herein is a generic semiconductor device comprising a plurality of semiconductor chips in a common housing in such a manner that interfering parasitic capacitances which act on critical signal lines are reduced and a higher signal transmission speed is thus enabled without the need for design changes to the semiconductor chip or to the semiconductor device including a plurality of semiconductor chips.

According to a first embodiment, a semiconductor device includes a plurality of semiconductor chips packaged in a common housing with signal pads which pass critical signals to the respective chips are terminated by a terminating resistance. Only some of at least two signal pads which are close to one another are connected to one another and are each arranged on different chips and receive the same signal are terminated by a terminating resistance.

If, in an inventive semiconductor device having two semiconductor chips which are arranged in a common housing in a flip-chip arrangement, for example, a first pad on the first semiconductor chip and a second pad which is connected to the first pad and is on the second semiconductor chip are close to one another, signal reflection by the first signal pad becomes negligible if the second pad has been terminated in a suitable manner. That is to say a terminating resistance of 50 Ω is suitable for a 50 Ω signal transmission system.

If, contrary to the inventive principle, terminating resistances were respectively provided for both pads, they would have to have an impedance of 100 Ω on each pad in order to achieve an overall termination of 50 Ω. Furthermore, in such a semiconductor device in which a plurality of semiconductor chips are packaged in a common housing, if both a 100 Ω termination and a 50 Ω termination were provided for the chips, the parasitic capacitances of the 50 Ω termination would also act on the 100 Ω termination. In such a semiconductor device, the parasitic capacitances would therefore be twice as high as in a special design for a 100 Ω terminating resistance.

In one advantageous embodiment, in the case of such signal pads which are connected to one another and for the situation in which the signal pads are respectively used to pass the same signal to the at least two chips via a longer signal connection and a signal connection which is shorter in comparison, only that signal pad which is connected to the longer signal connection is terminated by a terminating resistance. Such a situation may exist when, for example, two chips which are on top of one another and have pads which point upward receive the same signal via a longer signal connecting line and a shorter signal connecting line. In the case of such a bonding connection, a parasitic inductance scattered to the upper chip by the longer bonding wire cannot be ignored and the pad of this chip must therefore be terminated by a suitable terminating resistance. In contrast, the pad of the lower chip having the respective shorter signal connecting line need not be terminated.

In addition, according to a second embodiment, a semiconductor device includes a plurality of semiconductor chips (or dies) packaged in a common housing with signal pads which pass critical signals to the respective chip are terminated by a terminating resistance, wherein each chip includes a plurality of signal pads each having a different terminating resistance for each critical signal, and wherein a selection circuit is provided on each chip in order to respectively select one of these signal pads and thus a desired terminating resistance from the plurality of different terminating resistances.

The solution proposed last is advantageous, for example in a semiconductor device, where each of a plurality of identical chips in the common housing requires multiple termination without parasitic capacitances or inductances playing a role.

The selection in the selection circuit is advantageously made by routing and connecting bonding wires in an appropriate manner. Although this takes up chip area, it is acceptable in solutions in which the chips do not have too many pads.

According to a third embodiment, a semiconductor device includes a plurality of semiconductor chips (or dies) packaged in a common housing with signal pads which pass critical signals to the respective chip and are terminated by a terminating resistance, wherein a plurality of different terminating resistances which are connected to a respective signal pad are provided on each chip and a fuse is provided for each terminating resistance, at least some of the terminating resistances being able to be disconnected from the signal pad by severing the fuse.

The relevant signal pads of each chip are connected to the terminating resistances to be selected via respective fusible links or fuses which can be severed electrically or via a laser beam or in another manner and can be used to disconnect some or all of the terminating resistances from the signal pad. The parasitic components can thus be minimized in this case by virtue of the disconnection.

Furthermore, the principles described above can be used in semiconductor chips which are designed for use in the abovementioned inventive semiconductor devices and in which signal pads which are used to pass critical signals to the chip are terminated by terminating resistances.

Exemplary embodiments of the semiconductor device and semiconductor chip are now described with reference to the figures.

It should be noted that the following description of the exemplary embodiments uses the terms semiconductor chip and semiconductor die synonymously.

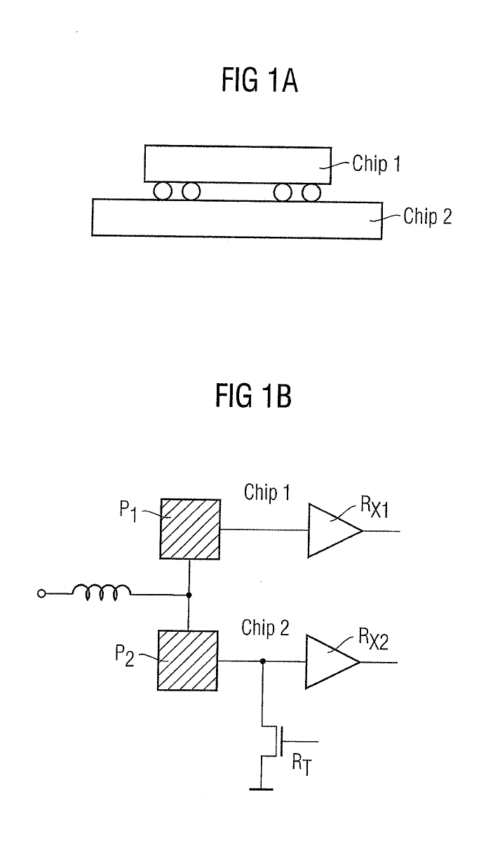

FIG. 1A shows an arrangement of two chips, chip 1 and chip 2, which are stacked on top of one another in a flip-chip arrangement. In this special case, as shown in FIG. 1B, two signal pads P1 and P2 are close to one another and are connected to one another since they supply the same signal, for example an address signal, to the two chips, chip 1 and chip 2. Therefore, if, as shown in FIG. 1B, the second pad P2 has been correctly terminated with a terminating resistance RT, the first pad P1 gives rise to only minimal reflection on the signal line which passes the same signal to a first receiver circuit RX1 on the first chip, chip 1, and to a second receiver circuit RX2 on the second chip, chip 2. The terminating resistance RT has a value of 50 Ω in a 50 Ω signal transmission system.

If both pads, P1 and P2, were terminated by a terminating resistance, the latter would respectively have to have a value of 100 Ω in order to realize an effective terminating resistance of 50 Ω.

A semiconductor chip which is intended to be used both as an individual chip in a housing or together with another semiconductor chip in a common housing would have to have both a 100 Ω terminating impedance and a 50 Ω terminating impedance so that the 50 Ω termination would then have a parasitic influence on the 100 Ω termination. In the case of a multichip semiconductor device in which, for example, two chips receive the same signal, the parasitic influences would thus be twice as high as in a refinement of the chip with only a 100 Ω termination.

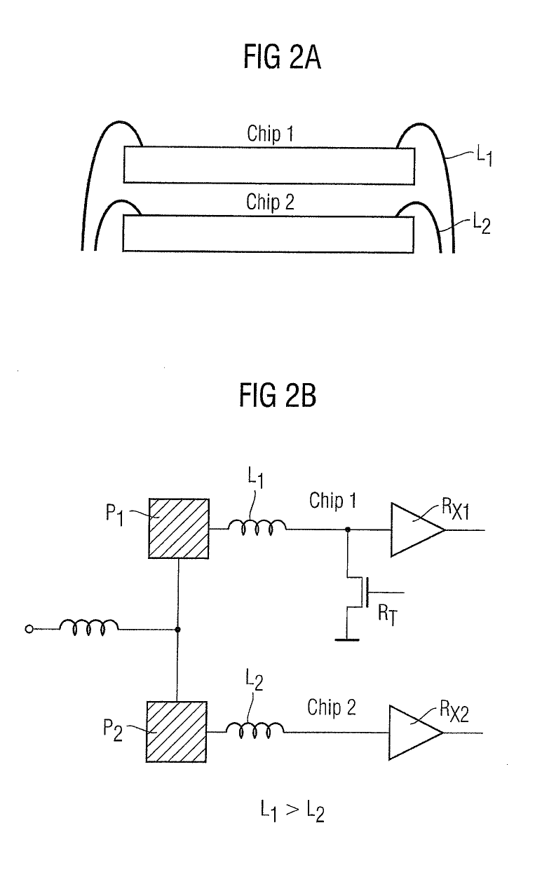

FIG. 2A shows a similar situation to that in FIG. 1A in which, for example, two semiconductor chips are arranged on top of one another in a so-called “face-up arrangement” and the pads of the chips, which supply the same signal, are connected to bonding wires L1 and L2 of different lengths. In this arrangement, the signal pads (not shown) are on the top side of the two chips.

In order to eliminate the parasitic components of the longer bonding wire L1 (which mainly has an inductive parasitic component), it is advantageous, as shown in FIG. 2B, to terminate the signal pad P1 of only the first (upper) chip, chip 1, by a terminating resistance RT, while the bonding wire L2 which is shorter in comparison is not terminated since its parasitic components are negligible.

In the two exemplary embodiments described, on the one hand, with reference to FIGS. 1A, 1B and, on the other hand, with reference to FIGS. 2A, 2B, the one terminating resistance RT thus also acts as a termination for the other signal line, that is to say the other pad P2, and the total parasitic components are thus reduced, which enables a higher transmission speed of the transmitted signal.

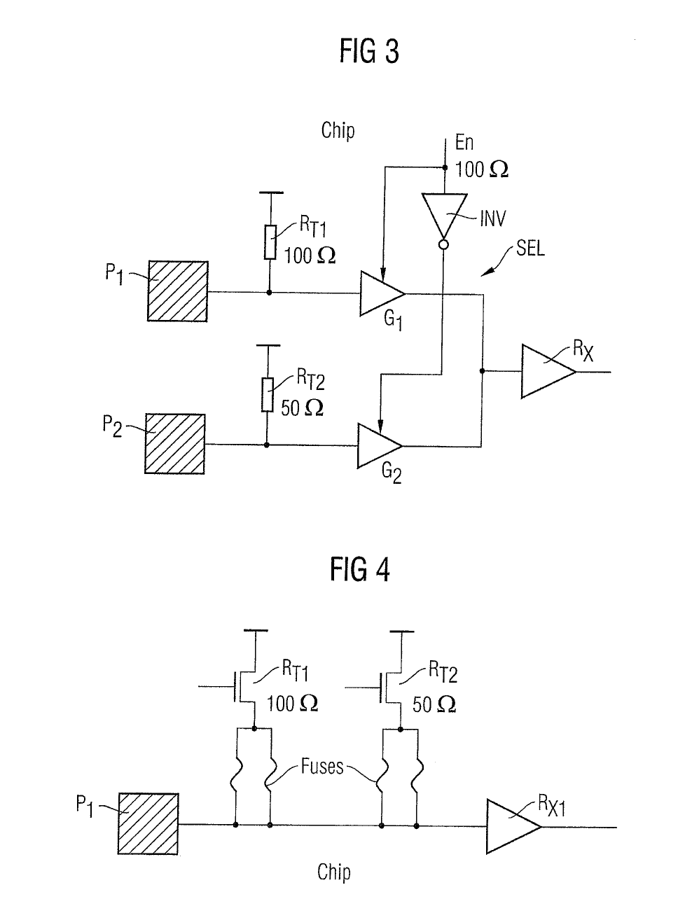

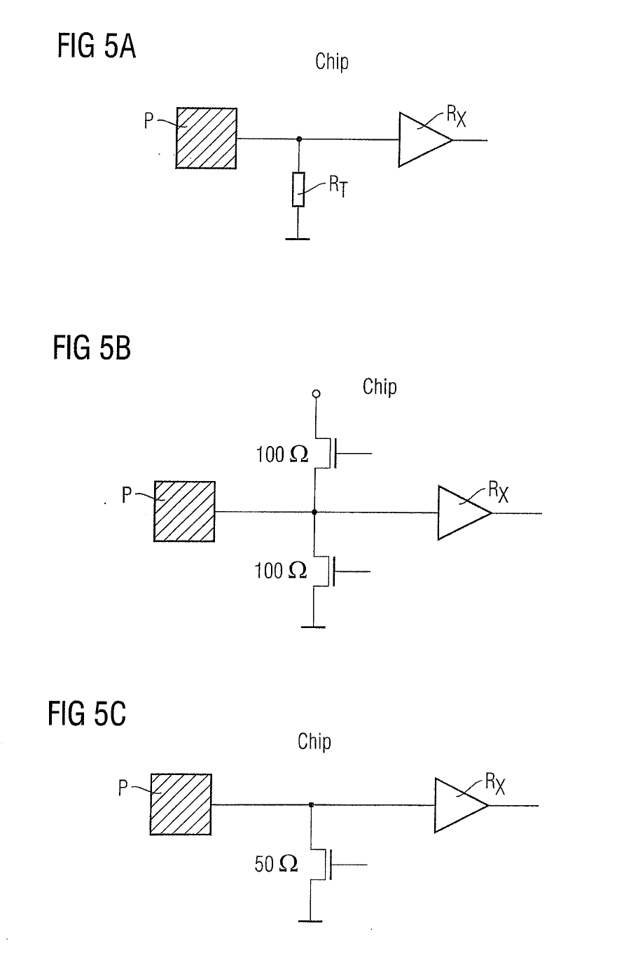

A third exemplary embodiment is shown in FIG. 3 which is particularly advantageous for a situation in which a plurality of, for example two, identical chips (or dies) are packaged in a common housing in order to make it possible to choose between a plurality of terminating resistances RT1, RT2 of different impedance, for example 100 Ω and 50 Ω. While the exemplary embodiment of FIG. 3 shows the implementation of two pads P1 and P2, any number of signal pads can be implemented. The chip also contains a selection circuit SEL which, in the example shown in FIG. 3, comprises a first gate G1, a second gate G2 and an inverter element INV and makes it possible to select a desired one of the two terminating resistances RT1, RT2. To this end, a bonding wire having a suitable potential can be connected to the input En of the selection circuit SEL. Although the practice of multiplying the pads, for example doubling them in this case, and the selection circuit require chip area, they are advantageous wherever the intention is to choose between a plurality of different terminating resistances of a semiconductor chip which has only relatively few pads in total.

FIG. 4 shows a fourth exemplary embodiment in which it is likewise possible to choose between a plurality of terminating resistances RT1 and RT2 of different impedance, for example 100 Ω and 50 Ω, or else of high impedance. According to FIG. 4, this is effected by virtue of the terminating resistances having the different impedances on the chip being connected to the signal line from the pad P1 by fuses which can be severed. The fuses may be metallic fuses, fuses which can be electrically severed or fuses which can be severed using laser beams, the fuses, when severed, disconnecting one or more of the terminating resistances RT1, RT2 from the common signal line.

The principles of the invention as illustrated using the exemplary embodiments described above also apply to semiconductor devices in which more than two chips are stacked on top of one another, for example for semiconductor devices having four stacked memory chips which have some of the signal lines in common.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A semiconductor device comprising:
a housing;
a plurality of semiconductor chips packaged in the housing; and
a plurality of signal pads to pass critical signals to the plurality of semiconductor chips, the plurality of signal pads comprising at least one set of signal pads that are disposed on separate semiconductor chips, are arranged in close proximity to each other and receive and pass the same critical signal, and are connected to each other, wherein one of the signal pads of the at least one set is terminated by a terminating resistance.

2. The semiconductor device of claim 1, wherein the at least one set of signal pads pass the same critical signal in a parallel manner with respect to each other.

3. The semiconductor device of claim 1, wherein the signal pads of the at least one set comprises two signal pads that are respectively connected to signal connections of different lengths, and the longer of the two respective signal connections is terminated by the terminating resistance.

4. The semiconductor device of claim 1, wherein a single signal pad of the plurality of signal pads is terminated by the terminating resistance.

5. A semiconductor chip comprising:
a plurality of terminating resistances;
a plurality of signal pads to pass critical signals to the chip, each signal pad including a different terminating resistance; and
a selection circuit to respectively select one of the signal pads and a respective terminating resistance of the selected signal pad.

6. A semiconductor device comprising:
a housing; and
a plurality of semiconductor chips as recited in claim 5, wherein the semiconductor chips are packaged in the housing.

7. A semiconductor chip comprising:
at least one signal pad to pass critical signals to the chip;
a plurality of different terminating resistances connected to each signal pad; and
a plurality of fuses operable to disconnect a respective terminating resistance from a respective signal pad in response to severing the fuse.

8. The semiconductor chip as claimed in claim 7, wherein the fuses are laser fuses.

9. The semiconductor chip as claimed in claim 7, wherein the fuses are electrical fuses.

10. A semiconductor device comprising:
a housing; and
a plurality of semiconductor chips as recited in claim 7, wherein the semiconductor chips are packaged in the housing.
